(19) United States
(12) Patent Application Publication
(10) Pub. No.: US 2020/0144553 A1
(43) Pub. Date: May 7, 2020

(54) ORGANIC EL DISPLAY DEVICE

(71) Applicant: NITTO DENKO CORPORATION, Ibaraki-shi, Osaka (JP)

(72) Inventors: Akiko Ogasawara, Ibaraki-shi (JP); Hiroyuki Takemoto, Ibaraki-shi (JP); Kentarou Takeda, Ibaraki-shi (JP); Koya Osuka, Ibaraki-shi (JP)

(73) Assignee: NITTO DENKO CORPORATION, Ibaraki-shi, Osaka (JP)

(21) Appl. No.: 16/336,570

(22) PCT Filed: Sep. 26, 2017
(86) PCT No.: PCT/JP2017/034750

§ 371 Date: Apr. 23, 2019

(30) Foreign Application Priority Data
Sep. 30, 2016 (JP) 2016-193900

(51) Int. Cl. H01L 51/52; H01L 27/32; B32B 7/10

(52) U.S. Cl. CPC H01L 51/5281; H01L 27/323; B32B 2457/206; H01L 2251/558; H01L 2251/5338; B32B 7/10

(57) ABSTRACT

Provided is an organic EL display apparatus which is excellent in bending resistance, and in which the occurrence of warping due to a change in its environment is suppressed. The organic EL display apparatus of the present invention includes: an organic EL panel; a first optical laminate arranged on one side of the organic EL panel; and a second optical laminate arranged on another side of the organic EL panel, wherein the first optical laminate has a thickness of 300 μm or less, wherein the second optical laminate has a thickness of 300 μm or less, wherein the first optical laminate has an equilibrium moisture content of 2.50 or less, and wherein the second optical laminate has an equilibrium moisture content of 2.5% or less.

### TECHNICAL FIELD

The present invention relates to an organic EL display apparatus.

### BACKGROUND ART

The number of opportunities for the use of a display apparatus for, for example, a smart device typified by a smart phone, digital signage, or a window display under strong ambient light has been increasing in recent years. Along with the increase, there has been occurring a problem such as: the reflection of the ambient light by the display apparatus itself or a reflector to be used in the display apparatus, such as a touch panel portion, a glass substrate, or a metal wiring; or the reflection of a background on the display apparatus or the reflector. In particular, an organic electroluminescence (EL) display apparatus that has started to be put into practical use in recent years is liable to cause a problem, such as the reflection of the ambient light or the reflection of the background because the apparatus has a metal layer having high reflectivity. In view of the foregoing, it is known that such problem is prevented by using an optical laminate having a predetermined function (e.g., a circularly polarizing plate serving as an antireflection film) (for example, Patent Literature

In recent years, there has been an increasing demand for an organic EL display apparatus that is flexible and bendable. An organic EL display apparatus having a high flexible property has various advantages, such as being excellent in lightness in weight, thinness, and flexibility, and also excellent in design property. An optical laminate to be used for such organic EL display apparatus having a high flexible property, in particular, a display apparatus capable of being folded, which is called foldable, is required to have high bending resistance (repeated bendability). In addition, while being thin and excellent in flexibility, the display apparatus is also required to be free of a change in shape, such as warping, due to a change in its environment.

### CITATION LIST

### Patent Literature

[PTL 1] JP 2006-171235 A

### SUMMARY OF INVENTION

### Technical Problem

The present invention has been made in order to solve the problems of the related art described above, and an object of the present invention is to provide an organic EL display apparatus which is excellent in bending resistance, and in which the occurrence of warping due to a change in its environment is suppressed.

### Solution to Problem

According to one embodiment of the present invention, there is provided an organic EL display apparatus, including: an organic EL panel; a first optical laminate arranged on one side of the organic EL panel; and a second optical laminate arranged on another side of the organic EL panel, wherein the first optical laminate has a thickness of 300 μm or less, wherein the second optical laminate has a thickness of 300 μm or less, wherein the first optical laminate has an equilibrium moisture content of 2.5% or less, and wherein the second optical laminate has an equilibrium moisture content of 2.5% or less.

In one embodiment, an absolute value of a difference between the thickness of the first optical laminate and the thickness of the second optical laminate is 150 μm or less.

In one embodiment, an absolute value of a difference between the equilibrium moisture content of the first optical laminate and the equilibrium moisture content of the second optical laminate is 1% or less.

In one embodiment, the first optical laminate has a tensile modulus of elasticity of from 1.5 GPa to 10 GPa at 25° C.

In one embodiment, the second optical laminate has a tensile modulus of elasticity of from 1.5 GPa to 10 GPa at 25° C.

In one embodiment, the first optical laminate includes at least a substrate, a polarizer, an optical compensation layer, and a pressure-sensitive adhesive layer in the stated order.

In one embodiment, the first optical laminate includes a conductive layer.

In one embodiment, the organic EL display apparatus preferably has a warping amount of 3 mm or less.

In one embodiment, the organic EL display apparatus is bendable with a radius of curvature of 10 mm or less.

### Advantageous Effects of Invention

According to the present invention, the organic EL display apparatus which is excellent in bending resistance, and in which the occurrence of warping due to a change in its environment is suppressed can be provided.

### BRIEF DESCRIPTION OF DRAWINGS

FIG. 1 is a schematic sectional view of an organic EL display apparatus according to one embodiment of the present invention.

FIG. 2 is a schematic sectional view for illustrating one mode of an organic EL panel to be used in the present invention.

FIG. 3 is a view for illustrating a folding endurance tester to be used for a folding endurance test in Examples and Comparative Examples.

### DESCRIPTION OF EMBODIMENTS

Now, typical embodiments of the present invention are described. However, the present invention is not limited to these embodiments.

(Definitions of Terms and Symbols)

The definitions of terms and symbols used herein are as described below.
(1) Refractive Indices (nx, ny, and nz)

“nx” represents a refractive index in a direction in which an in-plane refractive index is maximum (that is, slow axis direction), “ny” represents a refractive index in a direction perpendicular to the slow axis in the plane (that is, fast axis direction), and “nz” represents a refractive index in a thickness direction.
(2) In-Plane Retardation (Re)

“Re(λ)” refers to an in-plane retardation of a film measured at 23° C. with light having a wavelength of λ nm. For example, “Re(450)” refers to an in-plane retardation of a film measured at 23° C. with light having a wavelength of 450 nm. The Re(λ) is determined from the equation “Re=(nx−ny)×d” when the thickness of a film is represented by d (nm).
(3) Thickness Direction Retardation (Rth)

“Rth (λ) ” refers to a thickness direction retardation of a film measured at 23° C. with light having a wavelength of 550 nm. For example, “Rth(450)” refers to a thickness direction retardation of a film measured at 23° C. with light having a wavelength of 450 nm. The Rth(λ) is determined from the equation “Rth=(nx−nz)×d” when the thickness of a film is represented by d (nm).
(4) Nz Coefficient

An Nz coefficient is determined from the equation “Nz=Rth/Re”.
(5) Alignment Fixed Layer of Liquid Crystal Compound

The term “alignment fixed layer” refers to a layer in which a liquid crystal compound is aligned in a predetermined direction and its alignment state is fixed. The “alignment fixed layer” is a concept encompassing an aligned cured layer obtained by curing a liquid crystal monomer.
(6) Angle

When reference is made to an angle in this description, the angle encompasses angles in both clockwise and counterclockwise directions unless otherwise stated.

A. Overall Configuration of Organic EL Display Apparatus

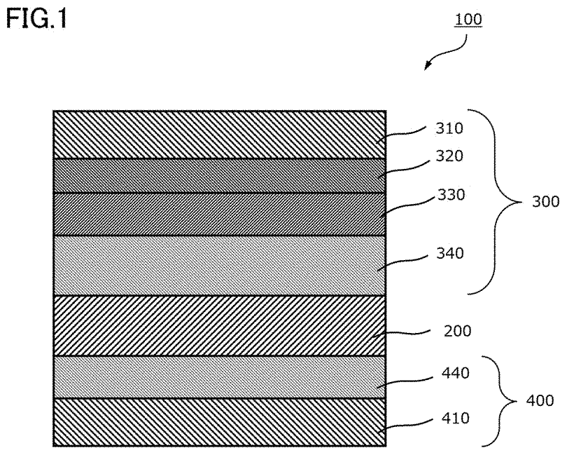

FIG. 1 is a schematic sectional view of an organic EL display apparatus according to one embodiment of the present invention. An organic EL display apparatus 100 according to this embodiment includes an organic EL panel 200, a first optical laminate 300 arranged on one side of the organic EL panel 200, and a second optical laminate 400 arranged on the other side of the organic EL panel 200.

In one embodiment, the first optical laminate 300 includes a polarizer 320 and an optical compensation layer 330 arranged on at least one side of the polarizer 320. In one embodiment, the laminate of the optical compensation layer 330 and the polarizer 320 functions as a circularly polarizing plate. The first optical laminate 300 is preferably arranged so that the polarizer 320 may be on a viewer side with respect to the optical compensation layer 330.

In one embodiment, the first optical laminate 300 includes a substrate 310, the polarizer 320, the optical compensation layer 330, and a pressure-sensitive adhesive layer 340 in the stated order. The first optical laminate 300 is preferably arranged on the viewer side of the organic EL panel 200 so that the substrate 310 may be on the viewer side. The substrate 310 is preferably flexible. In one embodiment, the substrate 310 has a function of substituting for a cover glass for the organic EL display apparatus as a surface protective layer, and also functions as a protective layer for the polarizer 320. As a result of substituting for the cover glass, the thinning of the optical laminate (consequently of the organic EL display apparatus) becomes possible. The substrate 310 and the polarizer 320 are preferably laminated via any appropriate adhesive (not shown).

The configuration of the first optical laminate is not limited to the configuration illustrated in FIG. 1, and may be any appropriate configuration. As required, any appropriate other layer may be further arranged, and any of the layers may be omitted depending on applications. In addition, the arrangement of each layer may be appropriately changed. Examples of the other layer include a conductive layer, a printed layer, a cover film, an antireflection layer, an antifouling layer, and a force sensor. The conductive layer may be arranged, for example, on the opposite side of the optical compensation layer 330 to the polarizer 320. When such conductive layer is arranged, the first optical laminate can be applied to a so-called inner touch panel-type input display apparatus, which includes a built-in touch sensor between an organic EL panel and a polarizer. The printed layer is formed, for example, at a peripheral portion of the first optical laminate (more specifically a position corresponding to the bezel of the organic EL display apparatus). The printed layer may be formed on the polarizer 320 side of the substrate 310, or may be formed on the opposite side of the optical compensation layer 330 to the polarizer 320. When the printed layer is formed on the opposite side of the optical compensation layer 330 to the polarizer 320, and both the conductive layer and the printed layer are formed, the printed layer maybe typically formed between the optical compensation layer and the conductive layer.

In one embodiment, the second optical laminate 400 includes a substrate 410 and a pressure-sensitive adhesive layer 440 arranged on the substrate. The substrate 410 may function as a surface protective layer for the organic EL panel 200. The substrate 410 is preferably flexible. The second optical laminate is preferably laminated on the organic EL panel 200 via the pressure-sensitive adhesive layer 440. The configuration of the second optical laminate is not limited to the configuration illustrated in FIG. 1, and may be any appropriate configuration. As required, any appropriate other layer may be further arranged.

The organic EL display apparatus is preferably bendable. More specifically, at least part of the organic EL display apparatus is bendable with a radius of curvature of preferably 10 mm or less, more preferably 8 mm or less. The organic EL display apparatus is bendable at any appropriate portion. For example, the organic EL display apparatus may be bendable at a central portion thereof like a folding display apparatus, or may be bendable at an end portion thereof from the viewpoint of securing a design property and a display screen to the fullest. Further, the organic EL display apparatus may be bendable along its lengthwise direction, or may be bendable along its transverse direction. Needless to say, a specific portion of the organic EL display apparatus only needs to be bendable (e.g., part or all of its four corners are bendable in oblique directions) depending on applications.

As described later, when the optical compensation layer is formed of a retardation film, the first optical laminate may be arranged so that the slow axis direction of the retardation film maybe preferably from 20° to 70°, more preferably from 30° to 60°, still more preferably from 40° to 50°, particularly preferably about 45° with respect to the bending direction of the organic EL display apparatus. As described later, when the optical compensation layer has a laminated structure of a first liquid crystal alignment fixed layer and a second liquid crystal alignment fixed layer, the first optical laminate may be arranged so that the slow axis direction of the first liquid crystal alignment fixed layer may be preferably from 10° to 20°, more preferably from 11° to 19°, still more preferably from 12° to 18°, particularly preferably about 15° with respect to the bending direction of the organic EL display apparatus. In this case, the slow axis direction of the second liquid crystal alignment fixed layer is preferably from 70° to 80°, more preferably from 71° to 79°, still more preferably from 72° to 78°, particularly preferably about 75° with respect to the bending direction of the organic EL display apparatus. The first liquid crystal alignment fixed layer and the second liquid crystal alignment fixed layer are extremely thin and little influenced by bending, and hence the adjustment of their axis angles does not need to be as precise as that in the case of the retardation film. In each of the embodiments, through the adjustment of the relationship between the slow axis direction of the optical compensation layer and the bending direction of the organic EL display apparatus, a bendable organic EL display apparatus in which a change in color due to bending is suppressed can be obtained. In one embodiment, the bending direction of the organic EL display apparatus is a lengthwise direction or a direction perpendicular to the lengthwise direction (transverse direction). In such embodiment, when the absorption axis of the polarizer of the optical laminate is set perpendicular or parallel to the lengthwise direction (or transverse direction), in the lamination on the organic EL panel, the position of the slow axis of the optical compensation layer does not need to be adjusted, and only the position of the absorption axis direction of the polarizer needs to be adjusted. In this manner, the organic EL display apparatus can be manufactured by a roll-to-roll process.

The warping amount of the organic EL display apparatus is preferably 3 mm or less, more preferably 1 mm or less. The warping amount is the average value of measured values obtained by placing the organic EL display apparatus (rectangular shape having a diagonal line of 5 inches) on a horizontal surface and measuring the height of each of its four corners from the horizontal surface.

B. First Optical Laminate

The thickness of the first optical laminate is 300 μm or less, preferably 280 μm or less, more preferably 260 μm or less, still more preferably 250 μm or less, particularly preferably 200 μm or less. When the thickness falls within such range, an organic EL display apparatus that is thin and excellent in bendability, and that is hardly broken even when repeatedly bent can be obtained. In addition, an organic EL display apparatus in which warping is reduced can be obtained. The lower limit of the thickness of the first optical laminate, which depends on its configuration, is, for example, 50 μm.

The thickness of the first optical laminate and the thickness of the second optical laminate may be identical to or different from each other. The absolute value of a difference between the thickness of the first optical laminate and the thickness of the second optical laminate is preferably 150 μm or less, more preferably 120 μm or less, still more preferably 100 μm or less, particularly preferably 50 μm or less. An organic EL display apparatus in which warping is further reduced can be obtained by reducing the difference between the thickness of the first optical laminate and the thickness of the second optical laminate.

The equilibrium moisture content of the first optical laminate is 2.5% or less. When the equilibrium moisture content falls within such range, an organic EL display apparatus in which the occurrence of warping due to a change in its temperature and humidity environment is suppressed can be obtained. The equilibrium moisture content of the optical laminate maybe adjusted on the basis of, the kinds and thicknesses of the constituent layers of the optical laminate. For example, when the optical laminate includes a layer having a relatively high moisture content (e.g., the polarizer or the pressure-sensitive adhesive layer), the equilibrium moisture content of the optical laminate is adjusted on the basis of, for example, the thickness and composition of the layer. The present invention has a feature in specifying the thicknesses of the optical laminates and appropriately adjusting the equilibrium moisture contents thereof, and as a result, warping of the organic EL display apparatus is remarkably suppressed. The term “equilibrium moisture content” as used herein refers to an equilibrium moisture content in the case where the optical laminate is left to stand at a humidity of 55% and a temperature of 23° C. for 24 hours. A measurement method for the “equilibrium moisture content” is described later.

The equilibrium moisture content of the first optical laminate is preferably 2% or less, more preferably 1.5% or less. When the equilibrium moisture content falls within such range, the above-mentioned effect of the present invention becomes more remarkable. The equilibrium moisture content of the first optical laminate is preferably as small as possible, but its lower limit is, for example, 0.3%.

The absolute value of a difference between the equilibrium moisture content of the first optical laminate and the equilibrium moisture content of the second optical laminate is preferably 1% or less, more preferably 0.8% or less, still more preferably 0.6% or less, particularly preferably 0.5% or less. An organic EL display apparatus having smaller warping can be obtained by reducing the difference between the equilibrium moisture content of the first optical laminate and the equilibrium moisture content of the second optical laminate.

When heated (80° C×24 h), the first optical laminate has a shrinkage ratio of preferably 1.0% or less, more preferably 0.8% or less, still more preferably 0.5% or less with respect to its area before the heating. When the shrinkage ratio falls within such range, the occurrence of warping due to a change in the environment can be suppressed.

The tensile modulus of elasticity of the first optical laminate is preferably from 1.5 GPa to 10 GPa, more preferably from 2 GPa to 8 GPa at 25° C. When the tensile modulus of elasticity falls within such range, the optical laminate can be made excellent in bendability and less liable to be broken. The tensile modulus of elasticity may be measured in conformity to JIS K 7127 (test piece: dumbbell test piece).

In one embodiment, the first optical laminate has an elongate shape. The optical laminate having an elongate shape may be, for example, rolled into a roll shape to be stored and/or transported.

Now, typical constituent elements of the first optical laminate are described.

B-1. Substrate

In one embodiment, the substrate includes a hard coat layer and a resin film. In the optical laminate, the hard coat layer may be arranged on the surface of the resin film on the opposite side to the polarizer. Depending on the configuration of the resin film, the hard coat layer may be omitted, or the hard coat layer may be formed on each of both sides of the resin film. The substrate may be formed by directly bonding the resin film or a laminate of the hard coat layer and the resin film to the polarizer, or may be formed by applying an application liquid containing a resin to be described later to the polarizer.

B-1-1. Characteristics of Substrate

The “substrate” in the following description of the characteristics of the substrate means: the resin film in the case of the resin film alone; and a laminate of the hard coat layer and the resin film in the case of including the hard coat layer and the resin film.

The substrate has such bendability as to allow the optical laminate to be bent preferably 200,000 times, more preferably 300,000 times, still more preferably 500,000 times with a radius of curvature of 3 mm or less (e.g., 3 mm, 2 mm, or 1 mm). When the substrate has such bendability, in the case of applying the optical laminate to an organic EL display apparatus, a bendable or foldable organic EL display apparatus can be realized. When the substrate has the hard coat layer on one side of the resin film, a test for the bendability is performed under a state in which the substrate is bent with the hard coat layer being on the inside. The bendability of the substrate may be measured with a folding endurance tester in which a chuck on one side repeats 180° bending across a mandrel.

The substrate preferably has restorability after bending. The restorability after bending refers to returning to the original state without a bending mark being left after bending. The restorability after bending may be evaluated, for example, on the basis of the number of times of repetition at which a bending mark is made after the substrate (resin film or laminate) has been repeatedly subjected to 180° bending with a radius of curvature of 1 mm. The substrate preferably has a restorability of 10,000 times or more under such conditions.

The viewer side surface (hard coat layer surface or resin film surface) of the substrate preferably has a pencil hardness of 9H or more. Further, the viewer side surface has such scratch resistance that the viewer side surface is free of occurrence of a flaw when rubbed back and forth with a load of 1,000 g preferably 300 times, more preferably 500 times, still more preferably 1,000 times. When the pencil hardness and the scratch resistance fall within such ranges, the substrate can satisfactorily function as a substitute for a cover glass. The pencil hardness may be measured in conformity to JIS K 5400-5-4. In addition, the scratch resistance may be evaluated on the basis of the state of a flaw formed when a surface is rubbed back and forth a predetermined number of times with steel wool #0000 at a load of 1,000 g.

The light transmittance of the substrate is preferably 91% or more, more preferably 93% or more, still more preferably 95% or more. The haze of the substrate is preferably 0.5% or less, more preferably 0.4% or less, still more preferably 0.3% or less. When the light transmittance and/or haze of the substrate falls within such range, in the case of applying the optical laminate to an organic EL display apparatus, satisfactory viewability can be realized.

B-1-2. Hard Coat Layer

The hard coat layer maybe formed of any appropriate material capable of satisfying the characteristics described in the section B-1-1. Specific examples of the constituent material include a thermosetting resin, a thermoplastic resin, an active energy ray-curable resin (e.g., a UV-curable resin or an electron beam-curable resin), and a two-component resin. Of those, a UV-curable resin is preferred. This is because the hard coat layer can be efficiently formed by a simple processing operation. Examples of the UV-curable resin include various resins, such as polyester-based, acrylic, urethane-based, amide-based, silicone-based, and epoxy-based resins. Those resins each contain, for example, a UV-curable monomer, oligomer, or polymer. Of those, an acrylic resin is preferred. The UV-curable acrylic resin contains a monomer component and an oligomer component each having preferably two or more, more preferably three to six UV-polymerizable functional groups. The UV-curable resin typically has blended therein a photopolymerization initiator. A curing mode may be a radical polymerization mode, or may be a cationic polymerization mode. In one embodiment, an organic-inorganic hybrid material obtained by blending silica particles, a cage silsesquioxane compound, or the like into the constituent material may be used. The constituent material and forming method for the hard coat layer are described in, for example, JP 2011-237789 A, the description of which is incorporated herein by reference.

The hard coat layer may be formed by blending a slide-ring material into the constituent material. When the slide-ring material is blended, satisfactory flexibility can be imparted. A typical example of the slide-ring material is polyrotaxane. The polyrotaxane typically has a structure in which cyclodextrin (CD) cyclic molecules slide on a linear polyethylene glycol (PEG) main chain. Both ends of the PEG main chain are modified with adamantanamine to prevent the CD cyclic molecules from falling off. In the polyrotaxane to be used in the present invention, the CD cyclic molecules are each chemically modified to have an active energy ray-polymerizable group. When the slide-ring material is used, a radically polymerizable monomer having a radically polymerizable group is preferably used as the constituent material for the hard coat layer. Examples of the radically polymerizable group include a (meth)acryloyl group and a (meth) acryloyloxy group. The radically polymerizable monomer is preferred because the radically polymerizable monomer is excellent in compatibility with the polyrotaxane and allows diverse material choices. When the polyrotaxane (substantially the polymerizable group of each of the CD cyclic molecules) and the active energy ray-curable component of the constituent material for the hard coat layer react with each other to be cured, there is obtained a hard coat layer in which cross-linking points are movable even after curing. As a result, a stress at the time of bending can be relaxed, and hence bending durability is improved. The polyrotaxane and the curing mechanism are described in, for example, JP 2015-155530 A, the description of which is incorporated herein by reference.

The hard coat layer may be formed by blending a nanofiber and/or a nanocrystal into the constituent material. Typical examples of the nanofiber include cellulose nanofiber, chitin nanofiber, and chitosan nanofiber. When those materials are blended, there can be obtained a hard coat layer that is excellent in flexibility, pencil hardness, scratch resistance, and abrasion resistance while maintaining excellent transparency. The nanofiber and/or the nanocrystal (total thereof in the case of combined use) may be blended at a ratio of preferably from 0.1 wt % to 40 wt % with respect to the entirety of the hard coat layer. The nanofiber has an average fiber diameter of, for example, from 1 nm to 100 nm, and an average fiber length of, for example, from 10 nm to 1,000 nm. The hard coat layer containing the nanofiber is described in, for example, JP 2012-131201 A and JP 2012-171171 A, the descriptions of which are incorporated herein by reference.

The thickness of the hard coat layer is preferably from 1 μm to 20 μm, more preferably from 2 μm to 15 μm. When the thickness is excessively small, hardness may be insufficient, and a suppressing effect on a dimensional change due to bending or the like may be insufficient. When the thickness is excessively large, bendability and/or foldability may be adversely affected.

B-1-3. Resin Film

The resin film may be formed of any appropriate material capable of satisfying the characteristics described in the section B-1-1. Specific examples of the constituent material include a polyethylene terephthalate-based resin, a polyethylene naphthalate-based resin, an acetate-based resin, a polyether sulfone-based resin, a polycarbonate-based resin, a polyamide-based resin, a polyimide-based resin, a polyamide-imide-based resin, a polyolefin-based resin, a (meth)acrylic resin, a polyvinyl chloride-based resin, a polyvinylidene chloride-based resin, a polystyrene-based resin, a polyvinyl alcohol-based resin, a polyarylate-based resin, and a polyphenylene sulfide-based resin. Those resins may be used alone or in combination thereof. Of those, a polyarylate-based resin and/or a polyimide-based resin is preferred.

Fine particles may be blended into the constituent material for the resin film. More specifically, the resin film may be a so-called nanocomposite film in which fine particles of the nanometer order are dispersed in a matrix made of the constituent material. With such configuration, extremely excellent hardness and scratch resistance are imparted, and hence the hard coat layer can be eliminated. The average particle diameter of the fine particles is, for example, from about 1 nm to about 100 nm. The fine particles are each typically formed of an inorganic oxide. The fine particles each preferably have a surface modified with a predetermined functional group. Examples of the inorganic oxide for forming the fine particles include zirconium oxide, yttria-doped zirconium oxide, lead zirconate, strontium titanate, tin titanate, tin oxide, bismuth oxide, niobium oxide, tantalum oxide, potassium tantalate, tungsten oxide, cerium oxide, lanthanum oxide, gallium oxide and the like, silica, alumina, titanium oxide, zirconium oxide, and barium titanate.

The thickness of the resin film is preferably from 5 μm to 100 μm, more preferably from 10 μm to 80 μm. With such thickness, an excellent balance among thinning, handleability, and mechanical strength is achieved.

B-2. Polarizer

Any appropriate polarizer may be adopted as the polarizer. For example, a resin film for forming the polarizer may be a single-layer resin film, or may be a laminate of two or more layers.

Specific examples of the polarizer formed of a single-layer resin film include: a polarizer obtained by subjecting a hydrophilic polymer film, such as a polyvinyl alcohol (PVA)-based film, a partially formalized PVA-based film, or an ethylene-vinyl acetate copolymer-based partially saponified film, to dyeing treatment with a dichroic substance, such as iodine or a dichroic dye, and stretching treatment; and a polyene-based alignment film, such as a dehydration-treated product of PVA or a dehydrochlorination-treated product of polyvinyl chloride. A polarizer obtained by dyeing the PVA-based film with iodine and uniaxially stretching the resultant is preferably used because the polarizer is excellent in optical characteristics.

The dyeing with iodine is performed by, for example, immersing the PVA-based film in an aqueous solution of iodine. The stretching ratio of the uniaxial stretching is preferably from 3 times to 7 times. The stretching may be performed after the dyeing treatment, or may be performed while the dyeing is performed. In addition, the dyeing maybe performed after the stretching has been performed. The PVA-based film is subjected to swelling treatment, cross-linking treatment, washing treatment, drying treatment, or the like as required. For example, when the PVA-based film is immersed in water to be washed with water before the dyeing, contamination or an antiblocking agent on the surface of the PVA-based film can be washed off. In addition, the PVA-based film is swollen and hence dyeing unevenness or the like can be prevented.

A specific example of the polarizer obtained by using a laminate is a polarizer obtained by using a laminate of a resin substrate and a PVA-based resin layer (PVA-based resin film) laminated on the resin substrate or a laminate of a resin substrate and a PVA-based resin layer formed on the resin substrate through application. The polarizer obtained by using the laminate of the resin substrate and the PVA-based resin layer formed on the resin substrate through application may be produced, for example, by: applying a PVA-based resin solution to the resin substrate; drying the solution to form the PVA-based resin layer on the resin substrate, to thereby provide the laminate of the resin substrate and the PVA-based resin layer; and stretching and dyeing the laminate to turn the PVA-based resin layer into the polarizer. In this embodiment, the stretching typically includes stretching of the laminate under a state in which the laminate is immersed in an aqueous solution of boric acid. Further, the stretching may further include in-air stretching of the laminate at high temperature (e.g., 95° C. or more) before the stretching in the aqueous solution of boric acid as required. The resultant laminate of the resin substrate and the polarizer maybe used as it is (i.e., the resin substrate may be used as a protective layer for the polarizer). Alternatively, a product obtained as described below may be used: the resin substrate is peeled from the laminate of the resin substrate and the polarizer, and any appropriate protective layer in accordance with purposes is laminated on the peeling surface. Details of such method of producing the polarizer are described in, for example, JP 2012-73580 A, the description of which is incorporated herein by reference in its entirety.

The thickness of the polarizer is preferably 25 μm or less, preferably 15 μm or less, more preferably 10 μm or less, still more preferably from 1 μm to 10 μm, still more preferably from 3 μm to 10 μm, particularly preferably from 3 μm to 8 μm. When the thickness of the polarizer falls within such range, curling at the time of heating can be satisfactorily suppressed, and satisfactory appearance durability at the time of heating is obtained. Further, when the thickness of the polarizer falls within such range, a contribution can be made to the thinning of the optical laminate (consequently of the organic EL display apparatus).

The polarizer preferably shows absorption dichroism at any wavelength in the wavelength range of from 380 nm to 780 nm. The single layer transmittance of the polarizer is preferably from 43.0% to 46.0%, more preferably from 44.5% to 46.0%. The polarization degree of the polarizer is preferably 97.0% or more, more preferably 99.0% or more, still more preferably 99.9% or more.

B-3. Optical Compensation Layer

In one embodiment, the optical compensation layer is formed of a retardation film. In this case, the retardation film may also function as a protective layer (inner protective layer) for the polarizer. As a result, a contribution can be made to further thinning of the optical laminate (consequently of the organic EL display apparatus). As required, an inner protective layer (inner protective film) may be arranged between the polarizer and the retardation film.

In another embodiment, the optical compensation layer has a laminated structure of alignment fixed layers of liquid crystal compounds (hereinafter referred to simply as liquid crystal alignment fixed layers). When the liquid crystal compounds are used, a difference between nx and ny of the optical compensation layer to be obtained can be markedly increased as compared to non-liquid crystal materials, and hence the thickness of the optical compensation layer for obtaining a desired in-plane retardation can be markedly reduced. As a result, further thinning of the optical laminate (consequently of the organic EL display apparatus) can be realized.

B-3-1. Optical Compensation Layer formed of Retardation Film

When the optical compensation layer is formed of a retardation film, the retardation film may function as a so-called λ/4 plate. The in-plane retardation Re (550) of the retardation film is preferably from 100 nm to 180 nm, more preferably from 135 nm to 155 nm.

The retardation film preferably satisfies a relationship of Re (450) <Re (550) <Re (650). That is, the retardation film preferably shows such reverse dispersion-type wavelength dependence that its retardation value increases with an increase in wavelength of measurement light. A ratio Re (450)/Re (550) of the retardation film is preferably 0.8 or more and less than 1.0, more preferably from 0.8 to 0.95. A ratio Re(550)/Re(650) of the retardation film is preferably 0.8 or more and less than 1.0, more preferably from 0.8 to 0.97.

The retardation film typically has: a refractive index characteristic of showing a relationship of nx>ny; and a slow axis. The angle formed between the slow axis of the retardation film and the absorption axis of the polarizer is preferably from. 35° to 55°, more preferably from 38° to 52°, still more preferably from 42° to 48°, particularly preferably about 45°. When the angle falls within such range, an optical laminate having an extremely excellent circular polarization characteristic (consequently an extremely excellent antireflection characteristic) can be obtained by using the retardation film as a λ/4 plate.

The retardation film shows any appropriate refractive index ellipsoid as long as the film has the relationship of nx>ny. The refractive index ellipsoid of the retardation film preferably shows a relationship of nx>ny≥nz. Herein, “ny=nz” encompasses not only a case in which ny and nz are exactly equal to each other, but also a case in which ny and nz are substantially equal to each other. Therefore, a relationship of ny<nz maybe satisfied without impairing the effect of the present invention. The Nz coefficient of the retardation film is preferably from 0.9 to 2, more preferably from 0.9 to 1.5, still more preferably from 0.9 to 1.3. When such relationship is satisfied, in the case of using the optical laminate for an organic EL display apparatus, an extremely excellent reflection hue can be achieved.

The absolute value of the photoelastic coefficient of the retardation film is preferably 2×10⁻¹² (m²/N) or more, more preferably from 10×10⁻¹² (m²/N) to 100×10⁻¹² (m²/N), still more preferably from 20×10⁻¹² (m²/N) to 40×10⁻¹² (m²/N). When the absolute value of the photoelastic coefficient falls within such range, the bendability of the organic EL display apparatus can be maintained while a sufficient retardation is secured even when the thickness is small. Moreover, a change in retardation (consequently a change in color of the organic EL display apparatus) due to a stress at the time of bending can be further suppressed.

The thickness of the retardation film is preferably from 1 μm to 70 μm, more preferably from 1 μm to 20 μm, still more preferably from 1 μm to 10 μm. In the optical laminate of the present invention, a film having a smaller thickness than a conventional λ/4 plate can be used while desired optical characteristics are maintained, and hence a contribution can be made to the thinning of the optical laminate (consequently of an organic EL display apparatus).

The retardation film is formed of any appropriate resin capable of satisfying such characteristics as described above. Examples of the resin for forming the retardation film include a polycarbonate resin, a polyvinyl acetal resin, a cycloolefin-based resin, an acrylic resin, and a cellulose ester-based resin. Of those, a polycarbonate resin is preferred.

As the polycarbonate resin, any appropriate polycarbonate resin maybe used as long as the effect of the present invention is obtained. The polycarbonate resin preferably contains: a structural unit derived from a fluorene-based dihydroxy compound; a structural unit derived from an isosorbide-based dihydroxy compound; and a structural unit derived from at least one dihydroxy compound selected from the group consisting of an alicyclic diol, an alicyclic dimethanol, di-, tri-, or polyethylene glycol, and an alkylene glycol or spiroglycol. The polycarbonate resin more preferably contains: a structural unit derived from a fluorene-based dihydroxy compound; a structural unit derived from an isosorbide-based dihydroxy compound; and a structural unit derived from an alicyclic dimethanol and/or a structural unit derived from di-, tri-, or polyethylene glycol. The polycarbonate resin still more preferably contains: a structural unit derived from a fluorene-based dihydroxy compound; a structural unit derived from an isosorbide-based dihydroxy compound; and a structural unit derived from di-, tri-, or polyethylene glycol. The polycarbonate resin may contain a structural unit derived from any other dihydroxy compound as required. Details of the polycarbonate resin that may be suitably used in the present invention are described in, for example, JP 2014-10291 A and JP 2014-26266 A, the descriptions of which are incorporated herein by reference.

The glass transition temperature of the polycarbonate resin is preferably 110° C. or more and 250° C. or less, more preferably 120° C. or more and 230° C. or less. When the glass transition temperature is excessively low, the heat resistance of the resin tends to deteriorate and hence the resin may cause a dimensional change after its forming into a film. In addition, the image quality of an organic EL display apparatus to be obtained may deteriorate. When the glass transition temperature is excessively high, the forming stability of the resin at the time of its forming into a film may deteriorate. In addition, the transparency of the film may be impaired. The glass transition temperature is determined in conformity to JIS K 7121 (1987).

The molecular weight of the polycarbonate resin maybe expressed as a reduced viscosity. The reduced viscosity is measured with an Ubbelohde viscometer at a temperature of 20.0° C±0.1° C. after precise adjustment of a polycarbonate concentration to 0.6 g/dL through the use of methylene chloride as a solvent. The lower limit of the reduced viscosity is generally preferably 0.30 dL/g, more preferably 0.35 dL/g or more. The upper limit of the reduced viscosity is generally preferably 1.20 dL/g, more preferably 1.00 dL/g, still more preferably 0.80 dL/g. When the reduced viscosity is lower than the lower limit value, there may arise a problem of a reduction in mechanical strength of a formed article. Meanwhile, when the reduced viscosity is higher than the upper limit value, there may arise a problem in that fluidity during forming is decreased to decrease productivity and formability.

The retardation film is obtained by, for example, stretching a film formed from the polycarbonate-based resin. Any appropriate forming method may be adopted as a method of forming a film from the polycarbonate-based resin. Specific examples thereof include a compression molding method, a transfer molding method, an injection molding method, an extrusion molding method, a blow molding method, a powder forming method, a FRP molding method, a cast coating method (e.g., a casting method), a calendar molding method, and a hot-press method. Of those, an extrusion molding method or a cast coating method is preferred. This is because the extrusion molding method or the cast coating method can increase the smoothness of the film to be obtained and provide satisfactory optical uniformity. Forming conditions may be appropriately set depending on, for example, the composition and kind of the resin to be used, and the desired characteristics of the retardation film.

The thickness of the resin film (unstretched film) may be set to any appropriate value depending on, for example, the desired thickness and desired optical characteristics of the retardation film to be obtained, and stretching conditions to be described later. The thickness is preferably from 50 μm to 300 μm.

Any appropriate stretching method and stretching conditions (e.g., a stretching temperature, a stretching ratio, and a stretching direction) may be adopted for the stretching. Specifically, one kind of various stretching methods, such as free-end stretching, fixed-end stretching, free-end shrinkage, and fixed-end shrinkage, may be employed alone, or two or more kinds thereof may be employed simultaneously or sequentially. With regard to the stretching direction, the stretching may be performed in various directions or dimensions, such as a lengthwise direction, a widthwise direction, a thickness direction, and an oblique direction.

A retardation film having the desired optical characteristics (e.g., a refractive index characteristic, an in-plane retardation, and an Nz coefficient) can be obtained by appropriately selecting the stretching method and stretching conditions.

In one embodiment, the retardation film is produced by subjecting a resin film to uniaxial stretching or fixed-end uniaxial stretching. A specific example of the fixed-end uniaxial stretching is a method involving stretching the resin film in its widthwise direction (lateral direction) while running the resin film in its lengthwise direction. The stretching ratio is preferably from 1.1 times to 3.5 times.

In another embodiment, the retardation film may be produced by continuously subjecting a resin film having an elongate shape to oblique stretching in the direction of a predetermined angle with respect to a lengthwise direction. When the oblique stretching is adopted, a stretched film having an elongate shape and having an alignment angle that is a predetermined angle with respect to the lengthwise direction of the film (having a slow axis in the direction of the predetermined angle) is obtained, and for example, its lamination with the polarizer can be performed by a roll-to-roll process. As a result, the manufacturing process can be simplified. The predetermined angle may be an angle formed between the absorption axis of the polarizer and the slow axis of the retardation layer in the optical laminate. As described above, the angle is preferably from 35° to 55°, more preferably from 38° to 52°, still more preferably from 42° to 48°.

As a stretching machine to be used for the oblique stretching, for example, there is given a tenter stretching machine capable of applying feeding forces, or tensile forces or take-up forces, having different speeds on left and right sides in a lateral direction and/or a longitudinal direction. Examples of the tenter stretching machine include a lateral uniaxial stretching machine and a simultaneous biaxial stretching machine, and any appropriate stretching machine may be used as long as the resin film having an elongate shape can be continuously subjected to the oblique stretching.

Through appropriate control of each of the speeds on the left and right sides in the stretching machine, a retardation film (substantially a retardation film having an elongate shape) having the desired in-plane retardation and having a slow axis in the desired direction can be obtained.

As a method for the oblique stretching, there are given, for example, methods described in JP 50-83482 A, JP 02-113920 A, JP 03-182701 A, JP 2000-9912 A, JP 2002-86554 A, JP 2002-22944 A, and the like.

The stretching temperature of the film may be changed depending on, for example, the desired in-plane retardation value and thickness of the retardation film, the kind of the resin to be used, the thickness of the film to be used, and a stretching ratio. Specifically, the stretching temperature is preferably from Tg−30° C. to Tg+30° C., more preferably from Tg−15° C. to Tg+15° C., most preferably from Tg−10° C. to Tg+10° C. When the stretching is performed at such temperature, a retardation film having characteristics that are appropriate in the present invention can be obtained. Tg refers to the glass transition temperature of the constituent material for the film.

A commercially available film may be used as the polycarbonate-based resin film. Specific examples of the commercially available product include products manufactured by Teijin Limited under the product names “PURE-ACE WR-S”, “PURE-ACE WR-W”, and “PURE-ACE WR-M”, and a product manufactured by Nitto Denko Corporation under the product name “NRF”. The commercially available film may be used as it is, or the commercially available film may be subjected to secondary processing (e.g., stretching treatment or surface treatment) before use depending on purposes.

(Inner Protective Layer)

When the inner protective layer (inner protective film) is arranged, it is preferred that the inner protective film be optically isotropic. The phrase “be optically isotropic” as used herein refers to having an in-plane retardation Re(550) of from 0 nm to 10 nm and a thickness direction retardation Rth(550) of from −10 nm to +10 nm.

The thickness of the inner protective film is preferably from 20 μm to 200 μm, more preferably from 30 μm to 100 μm, still more preferably from 35 μm to 95 μm.

The inner protective film is formed of any appropriate film as long as the desired characteristics are obtained. As a material serving as a main component of the film, there are specifically given, for example, cellulose-based resins, such as triacetylcellulose (TAC), and transparent resins, such as polyester-based, polyvinyl alcohol-based, polycarbonate-based, polyamide-based, polyimide-based, polyether sulfone-based, polysulfone-based, polystyrene-based, polynorbornene-based, polyolefin-based, (meth)acrylic, and acetate-based resins. There are also given, for example, thermosetting resins or UV-curable resins, such as (meth)acrylic, urethane-based, (meth)acrylic urethane-based, epoxy-based, and silicone-based resins. There are also given, for example, glassy polymers, such as a siloxane-based polymer. In addition, a polymer film described in JP 2001-343529 A (WO 01/37007 A1) may be used. For example, a resin composition containing a thermoplastic resin having a substituted or unsubstituted imide group on a side chain thereof, and a thermoplastic resin having a substituted or unsubstituted phenyl group and a nitrile group on side chains thereof may be used as a material for the film, and the composition is, for example, a resin composition containing an alternating copolymer formed of isobutene and N-methylmaleimide, and an acrylonitrile-styrene copolymer. The polymer film may be, for example, an extrudate of the resin composition.

B-3-2. Optical Compensation Layer formed of Laminate of Liquid Crystal Alignment Fixed Layers

In one embodiment, the optical compensation layer formed of a laminate of liquid crystal alignment fixed layers includes a first liquid crystal alignment fixed layer and a second liquid crystal alignment fixed layer. In the optical laminate, the optical compensation layer may include the first liquid crystal alignment fixed layer and the second liquid crystal alignment fixed layer in the stated order from a polarizer side.

(First Liquid Crystal Alignment Fixed Layer)

The first liquid crystal alignment fixed layer may function as a so-called λ/2 plate. An optical laminate having an excellent circular polarization characteristic in a wide band can be obtained by using the first liquid crystal alignment fixed layer as the so-called λ/2 plate, using the second liquid crystal alignment fixed layer to be described later as a so-called λ/4 plate, and setting their slow axes to predetermined directions with respect to the absorption axis of the polarizer. The in-plane retardation Re (550) of the first liquid crystal alignment fixed layer is preferably from 180 nm to 320 nm, more preferably from 200 nm to 290 nm, still more preferably from 230 nm to 280 nm.

The refractive index ellipsoid of the first liquid crystal alignment fixed layer typically shows a relationship of nx>ny=nz. The angle formed between the slow axis of the first liquid crystal alignment fixed layer and the absorption axis of the polarizer is preferably from 10° to 20°, more preferably from 13° to 17°, still more preferably about 15°. When the angle formed between the slow axis of the first liquid crystal alignment fixed layer and the absorption axis of the polarizer falls within such range, an optical laminate having an extremely excellent circular polarization characteristic (consequently an extremely excellent antireflection characteristic) in a wide band can be obtained by setting each of the in-plane retardations of the first liquid crystal alignment fixed layer and the second liquid crystal alignment fixed layer to a predetermined range, and arranging the slow axis of the second liquid crystal alignment fixed layer at a predetermined angle as described later with respect to the absorption axis of the polarizer.

The thickness of the first liquid crystal alignment fixed layer is preferably from 1 μm to 7 μm, more preferably from 1.5 μm to 2.5 μm. As described above, when the liquid crystal compounds are used, the difference between nx and ny of the optical compensation layer to be obtained can be markedly increased as compared to non-liquid crystal materials, and hence the layer thickness for obtaining a desired in-plane retardation can be markedly reduced. Accordingly, an in-plane retardation comparable to that of a resin film can be realized with a markedly smaller thickness than that of the resin film.

In this embodiment, in the first liquid crystal alignment fixed layer, a rod-shaped liquid crystal compound is typically aligned in a state of being aligned in a predetermined direction (homogeneous alignment). A slow axis may be expressed in the alignment direction of the liquid crystal compound. An example of the liquid crystal compound is a liquid crystal compound whose liquid crystal phase is a nematic phase (nematic liquid crystal). As such liquid crystal compound, for example, a liquid crystal polymer or a liquid crystal monomer may be used. The expression mechanism of the liquid crystallinity of the liquid crystal compound may be lyotropic or thermotropic. The liquid crystal polymer and the liquid crystal monomer may each be used alone, or may be used in combination.

When the liquid crystal compound is the liquid crystal monomer, the liquid crystal monomer is preferably a polymerizable monomer or a cross-linkable monomer. This is because the alignment state of the liquid crystal monomer can be fixed by polymerizing or cross-linking (that is, curing) the liquid crystal monomer. After the alignment of the liquid crystal monomer, for example, when liquid crystal monomers are polymerized or cross-linked with each other, the alignment state can be fixed as a result. In this case, a polymer is formed through the polymerization and a three-dimensional network structure is formed through the cross-linking, and the polymer and the structure are non-liquid crystalline. Therefore, the formed first liquid crystal alignment fixed layer does not undergo, for example, a transition caused by a temperature change to a liquid crystal phase, a glass phase, or a crystal phase, which is peculiar to a liquid crystalline compound. As a result, the first liquid crystal alignment fixed layer becomes a layer that is extremely excellent in stability without being affected by a temperature change.

The temperature range in which the liquid crystal monomer shows liquid crystallinity varies depending on its kind. Specifically, the temperature range is preferably from 40° C. to 120° C., more preferably from 50° C. to 100° C., most preferably from 60° C. to 90° C.

Any appropriate liquid crystal monomer may be adopted as the liquid crystal monomer. For example, a polymerizable mesogenic compound described in, for example, JP 2002-533742 A (WO 00/37585 A1), EP 358208 A (US 5211877 A), EP 66137 A (US 4388453 A), WO 93/22397 A1, EP 0261712 A, DE 19504224 A, DE 4408171 A, or GB 2280445 A, maybe used. Specific examples of such polymerizable mesogenic compound include a product available under the product name LC242 from. BASF SE, a product available under the product name E7 from Merck KGaA, and a product available under the product name LC-Sillicon-CC3767 from Wacker Chemie AG. The liquid crystal monomer is preferably, for example, a nematic liquid crystal monomer.

The first liquid crystal alignment fixed layer may be formed by: subjecting the surface of a predetermined substrate to alignment treatment; applying an application liquid containing a liquid crystal compound onto the surface; aligning the liquid crystal compound in a direction corresponding to the alignment treatment; and fixing the alignment state. When such alignment treatment is used, the liquid crystal compound can be aligned in a predetermined direction with respect to the elongate direction of an elongate substrate, and as a result, a slow axis can be expressed in a predetermined direction of the liquid crystal alignment fixed layer to be formed. For example, a liquid crystal alignment fixed layer having a slow axis in a direction of 15° with respect to the elongate direction can be formed on the elongate substrate. Even when desired to have a slow axis in an oblique direction, such liquid crystal alignment fixed layer can be laminated using a roll-to-roll process, and hence can markedly improve the productivity of the optical laminate. In one embodiment, the substrate is any appropriate resin film, and the alignment fixed layer formed on the substrate may be transferred onto the surface of the polarizer. In another embodiment, the substrate maybe the inner protective layer (inner protective film). In this case, the transfer step is eliminated, and hence lamination can be performed by a roll-to-roll process continuously from the formation of the alignment fixed layer.

Any appropriate alignment treatment may be adopted as the alignment treatment. Specific examples thereof include mechanical alignment treatment, physical alignment treatment, and chemical alignment treatment. Specific examples of the mechanical alignment treatment include rubbing treatment and stretching treatment. Specific examples of the physical alignment treatment include magnetic field alignment treatment and electric field alignment treatment. Specific examples of the chemical alignment treatment include an oblique deposition method and photoalignment treatment. Any appropriate conditions may be adopted as treatment conditions for the various alignment treatments depending on purposes.

The alignment of the liquid crystal compound is performed through treatment at a temperature at which the liquid crystal compound shows a liquid crystal phase depending on the kind of the liquid crystal compound. When the treatment at such temperature is performed, the liquid crystal compound adopts a liquid crystal state, and the liquid crystal compound is aligned depending on the alignment treatment direction of the surface of the substrate.

In one embodiment, the fixation of the alignment state is performed by cooling the liquid crystal compound aligned as described above. When the liquid crystal compound is the polymerizable monomer or the cross-linkable monomer, the fixation of the alignment state is performed by subjecting the liquid crystal compound aligned as described above to polymerization treatment or cross-linking treatment.

Specific examples of the liquid crystal compound and details of the method of forming the alignment fixed layer are described in JP 2006-163343 A, the description of which is incorporated herein by reference.

(Second Liquid Crystal Alignment Fixed Layer)

The second liquid crystal alignment fixed layer may function as a so-called λ/4 plate. An optical laminate having an excellent circular polarization characteristic in a wide band can be obtained by using the second liquid crystal alignment fixed layer as the so-called λ/4 plate, using the first liquid crystal alignment fixed layer as the so-called λ/2 plate as described above, and setting their slow axes to predetermined directions with respect to the absorption axis of the polarizer. As described above, the in-plane retardation Re(550) of the second liquid crystal alignment fixed layer is preferably from 100 nm to 180 nm, more preferably from 110 nm to 170 nm, still more preferably from 120 nm to 160 nm.

The refractive index ellipsoid of the second liquid crystal alignment fixed layer typically shows a relationship of nx>ny=nz. The angle formed between the slow axis of the second liquid crystal alignment fixed layer and the absorption axis of the polarizer is preferably from 65° to 85° as described above, and is more preferably from. 72° to 78°, still more preferably about 75°. When the angle formed between the slow axis of the second liquid crystal alignment fixed layer and the absorption axis of the polarizer falls within such range, an optical laminate having an extremely excellent circular polarization characteristic (consequently an extremely excellent antireflection characteristic) in a wide band can be obtained by setting each of the in-plane retardations of the first liquid crystal alignment fixed layer and the second liquid crystal alignment fixed layer to a predetermined range, and arranging the slow axis of the first liquid crystal alignment fixed layer at a predetermined angle as described above with respect to the absorption axis of the polarizer.

The thickness of the second liquid crystal alignment fixed layer is preferably from 0.5 μm to 2 μm, more preferably from 1 μm to 1.5 μm.

The constituent material, characteristics, production method, and the like of the second liquid crystal alignment fixed layer are as described in the section D-2-1 for the first liquid crystal alignment fixed layer.

Although an embodiment in which the angle formed between the slow axis of the first liquid crystal alignment fixed layer and the absorption axis of the polarizer is about 15°, and in which the angle formed between the slow axis of the second liquid crystal alignment fixed layer and the absorption axis of the polarizer is about 75° has been described, the axis angle relationships may be reversed. Specifically, the angle formed between the slow axis of the first liquid crystal alignment fixed layer and the absorption axis of the polarizer may be preferably from 65° to 85°, more preferably from 72° to 78°, still more preferably about 75°. In this case, the angle formed between the slow axis of the second liquid crystal alignment fixed layer and the absorption axis of the polarizer may be preferably from 10° to 20°, more preferably from 13° to 17°, still more preferably about 15°.

B-4. Pressure-sensitive Adhesive Layer or Adhesive Layer

Any appropriate pressure-sensitive adhesive layer or adhesive layer is used for the lamination of the constituent layers of the optical laminate.

An adhesive of any appropriate form may be adopted as an adhesive for forming the adhesive layer. Specific examples thereof include an aqueous adhesive, a solvent-type adhesive, an emulsion-based adhesive, a solvent-free adhesive, an active energy ray-curable adhesive, and a thermosetting adhesive. Examples of the active energy ray-curable adhesive include an electron beam-curable adhesive, a UV-curable adhesive, and a visible light-curable adhesive. Of those, an aqueous adhesive and an active energy ray-curable adhesive maybe suitably used. Specific examples of the aqueous adhesive include an isocyanate-based adhesive, a polyvinyl alcohol-based adhesive (PVA-based adhesive), a gelatin-based adhesive, a vinyl-based latex-based adhesive, aqueous polyurethane, and aqueous polyester. A specific example of the active energy ray-curable adhesive is a (meth) acrylate-based adhesive. The “ (meth) acrylate” means acrylate and/or methacrylate. In the (meth)acrylate-based adhesive, examples of the curable component include a compound having a (meth)acryloyl group and a compound having a vinyl group. In addition, as a cationic polymerization-curable adhesive, a compound having epoxy groups or oxetanyl groups may also be used. The compound having epoxy groups is not particularly limited as long as the compound has at least two epoxy groups in the molecule, and generally known various curable epoxy compounds may be used. Preferred examples of the epoxy compounds include: a compound having, in the molecule, at least two epoxy groups and at least one aromatic ring (aromatic epoxy compound); and a compound having, in the molecule, at least two epoxy groups, at least one of which is formed between two adjacent constituent carbon atoms of an alicyclic ring (alicyclic epoxy compound).

In one embodiment, a PVA-based adhesive is used as the adhesive for forming the adhesive layer. Through the use of the PVA-based adhesive, even when materials that do not transmit active energy rays are used, the materials can be bonded to each other. In another embodiment, an active energy ray-curable adhesive is used as the adhesive for forming the adhesive layer. Through the use of the active energy ray-curable adhesive, sufficient delamination strength can be obtained even for a material that has a hydrophobic surface and cannot be bonded with a PVA adhesive.

The storage modulus of elasticity of the adhesive layer is preferably 1.0×10⁶ Pa or more, more preferably 1.0×10⁷ Pa or more in a region of 70° C. or less. The upper limit of the storage modulus of elasticity of the adhesive layer is, for example, 1.0×10¹° Pa. The storage modulus of elasticity of the adhesive layer influences polarizer cracking in the application of a heat cycle (e.g., from −40° C. to 80° C.) to the optical laminate. When the storage modulus of elasticity is low, the problem of polarizer cracking is liable to occur. The adhesive layer has a high storage modulus of elasticity in a temperature region of more preferably 80° C. or less, still more preferably 90° C. or less.

The thickness of the adhesive layer is typically from 0.01 μm to 7 μm, preferably from 0.01 μm to 5 μm.

The adhesive layer or the pressure-sensitive adhesive layer may be used for lamination other than the lamination of the substrate and the polarizer.

Examples of the pressure-sensitive adhesive for forming the pressure-sensitive adhesive layer include an acrylic pressure-sensitive adhesive, a rubber-based pressure-sensitive adhesive, a vinyl alkyl ether-based pressure-sensitive adhesive, a silicone-based pressure-sensitive adhesive, a polyester-based pressure-sensitive adhesive, a polyamide-based pressure-sensitive adhesive, a urethane-based pressure-sensitive adhesive, a fluorine-based pressure-sensitive adhesive, an epoxy-based pressure-sensitive adhesive, and a polyether-based pressure-sensitive adhesive. The pressure-sensitive adhesives may be used alone or in combination thereof. Of those, an acrylic pressure-sensitive adhesive is preferably used from the viewpoints of transparency, processability, durability, and the like.

The thickness of the pressure-sensitive adhesive layer is typically from 10 μm to 250 μm, preferably from 10 μm to 150 μm. The pressure-sensitive adhesive layer may be a single layer, or may have a laminated structure.

The storage modulus of elasticity (G′) of the pressure-sensitive adhesive layer is preferably from 0.01 MPa to 1.00 MPa, more preferably from 0.05 MPa to 0.50 MPa at 25° C. When the storage modulus of elasticity of the pressure-sensitive adhesive layer falls within such range, an optical laminate having extremely excellent bendability can be obtained. As a result, a bendable or foldable organic EL display apparatus can be realized.

B-5. Conductive Layer

The conductive layer is typically transparent (that is, the conductive layer is a transparent conductive layer). When the conductive layer is formed on the opposite side of the optical compensation layer to the polarizer, the optical laminate can be applied to a so-called inner touch panel-type input display apparatus, which includes a built-in touch sensor between a display cell (organic EL cell) and a polarizer.

The conductive layer may be used alone as a constituent layer of the optical laminate, or may be laminated as a laminate with a substrate (conductive layer with a substrate) on the optical compensation layer. When the configuration in which the conductive layer is used alone is adopted, the conductive layer may be transferred onto the optical compensation layer from a substrate on which the conductive layer has been formed.

The conductive layer may be patterned as required. Through the patterning, a conductive part and an insulating part may be formed. As a result, an electrode may be formed. The electrode may function as a touch sensor electrode for detecting contact on a touch panel. The shape of the pattern is preferably a pattern that satisfactorily operates as a touch panel (e.g., a capacitance-type touch panel). Specific examples thereof include patterns described in, for example, JP 2011-511357 A, JP 2010-164938 A, JP 2008-310550 A, JP 2003-511799 A, and JP 2010-541109 A.

The total light transmittance of the conductive layer is preferably 80% or more, more preferably 85% or more, still more preferably 90% or more. For example, when a conductive nanowire to be described later is used, a transparent conductive layer having formed therein an opening can be formed, and hence a transparent conductive layer having a high light transmittance can be obtained.

The density of the conductive layer is preferably from 1.0 g/cm³ to 10.5 g/cm³, more preferably from 1.3 g/cm³ to 3.0 g/cm³.

The surface resistance value of the conductive layer is preferably from 0.1 Ω/□ to 1,000 Ω/□, more preferably from 0.5 Ω/□ to 500 Ω/□, still more preferably from 1 Ω/□ to 250 Ω/□.

Typical examples of the conductive layer include a conductive layer including a metal oxide, a conductive layer including a conductive nanowire, and a conductive layer including a metal mesh. Of those, a conductive layer including a conductive nanowire or a conductive layer including a metal mesh is preferred. This is because such material is excellent in bending resistance and hardly loses conductivity even when bent, and hence a conductive layer capable of being satisfactorily bent can be formed.

The conductive layer including a metal oxide may be formed by forming a metal oxide film on any appropriate substrate by any appropriate film forming method (e.g., a vacuum deposition method, a sputtering method, a CVD method, an ion plating method, or a spraying method). Examples of the metal oxide include indium oxide, tin oxide, zinc oxide, indium-tin composite oxide, tin-antimony composite oxide, zinc-aluminum composite oxide, and indium-zinc composite oxide. Of those, indium-tin composite oxide (ITO) is preferred.

The conductive layer including a conductive nanowire may be formed by applying a dispersion liquid obtained by dispersing the conductive nanowire in a solvent (conductive nanowire dispersion liquid) onto any appropriate substrate, and then drying the applied layer. Any appropriate conductive nanowire may be used as the conductive nanowire as long as the effect of the present invention is obtained. The conductive nanowire refers to a conductive substance that has a needle- or thread-like shape and has a diameter of the order of nanometers. The conductive nanowire maybe linear or maybe curved. As described above, the conductive layer including the conductive nanowire is excellent in bending resistance. In addition, when the conductive layer including the conductive nanowire is used, pieces of the conductive nanowire form a gap therebetween to be formed into a network shape. Accordingly, even when a small amount of the conductive nanowire is used, a good electrical conduction path can be formed and hence a conductive layer having a small electrical resistance can be obtained. Further, the conductive nanowire is formed into a network shape, and hence an opening portion is formed in a gap of the network. As a result, a conductive layer having a high light transmittance can be obtained. Examples of the conductive nanowire include a metal nanowire formed of a metal and a conductive nanowire including a carbon nanotube.

A ratio (aspect ratio: L/d) between a thickness d and a length L of the conductive nanowire is preferably from 10 to 100,000, more preferably from 50 to 100,000, still more preferably from 100 to 10,000. When a conductive nanowire having such large aspect ratio as described above is used, the conductive nanowire satisfactorily intersects with itself and hence high conductivity can be expressed with a small amount of the conductive nanowire. As a result, a conductive layer having a high light transmittance can be obtained. The term “thickness of the conductive nanowire” as used herein has the following meanings: when a section of the conductive nanowire has a circular shape, the term means the diameter of the circle; when the section has an elliptical shape, the term means the short diameter of the ellipse; and when the section has a polygonal shape, the term means the longest diagonal of the polygon. The thickness and length of the conductive nanowire may be observed with a scanning electron microscope or a transmission electron microscope.

The thickness of the conductive nanowire is preferably less than 500 nm, more preferably less than 200 nm, still more preferably from 1 nm to 100 nm, particularly preferably from 1 nm to 50 nm. When the thickness falls within such range, a conductive layer having a high light transmittance can be formed. The length of the conductive nanowire is preferably from 2.5 μm to 1,000 μm, more preferably from 10 μm to 500 μm, still more preferably from 20 μm to 100 μm. When the length falls within such range, a conductive layer having high conductivity can be obtained.

Any appropriate metal may be used as a metal for forming the conductive nanowire (metal nanowire) as long as the metal has high conductivity. The metal nanowire is preferably formed of one or more kinds of metals selected from the group consisting of gold, platinum, silver, and copper. Of those, silver, copper, or gold is preferred from the viewpoint of conductivity, and silver is more preferred. In addition, a material obtained by subjecting the metal to metal plating (e.g., gold plating) may be used.

Any appropriate carbon nanotube may be used as the carbon nanotube. For example, a so-called multi-walled carbon nanotube, double-walled carbon nanotube, or single-walled carbon nanotube is used. Of those, a single-walled carbon nanotube is preferably used because of its high conductivity.

As the metal mesh, any appropriate metal mesh may be used as long as the effect of the present invention is obtained. For example, there may be used a metal wiring layer arranged on a film substrate and formed into a mesh pattern.

Details of the conductive nanowire and the metal mesh are described in, for example, JP 2014-113705 A and JP 2014-219667 A, the descriptions of which are incorporated herein by reference.

The thickness of the conductive layer is preferably from 0.01 μm to 10 μm, more preferably from 0.05 μm to 3 μm, still more preferably from 0.1 μm to 1 μm. When the thickness falls within such range, a conductive layer excellent in conductivity and light transmittance can be obtained. When the conductive layer includes the metal oxide, the thickness of the conductive layer is preferably from 0.01 μm to 0.05 μm.

B-6. Printed Layer

As described above, the printed layer is formed at the peripheral portion of the optical laminate, more specifically the position corresponding to the bezel of an organic EL display apparatus in plan view. Also as described above, the printed layer maybe formed on the polarizer side of the substrate (substantially the polarizer side of the resin film), or may be formed on the opposite side of the optical compensation layer to the polarizer. The printed layer may be a design layer provided with a predetermined design, or may be a solid colored layer. The printed layer is preferably a solid colored layer, more preferably a black colored layer. When the black colored layer is formed at the position corresponding to the bezel, a non-display region can be concealed, and hence an organic EL display apparatus using no bezel can be realized through the use of the optical laminate according to this embodiment. As a result, an organic EL display apparatus having an extremely excellent appearance without any step on its outermost surface can be provided. Further, when the printed layer is formed on the optical compensation layer, the following advantage is obtained. That is, with such configuration, the printed layer is inevitably arranged below the polarizer (on the organic EL display apparatus side), and as a result, reflected light at an interface of the printed layer is reduced by the polarizer. Therefore, an organic EL display apparatus having a more excellent appearance can be realized.

The printed layer may be formed by any appropriate printing method using any appropriate ink or paint. Specific examples of the printing method include gravure printing, offset printing, silkscreen printing, and transfer printing from a transfer sheet.

The ink or paint to be used typically contains a binder, a colorant, a solvent, and any appropriate additive that may be used as required. Examples of the binder include chlorinated polyolefins (e.g., chlorinated polyethylene and chlorinated polypropylene), a polyester-based resin, a urethane-based resin, an acrylic resin, a vinyl acetate resin, a vinyl chloride-vinyl acetate copolymer, and a cellulose-based resin. The binder resins may be used alone or in combination thereof. In one embodiment, the binder resin is a thermally polymerizable resin. The thermally polymerizable resin only needs to be used in a small amount as compared to a photopolymerizable resin, and hence the usage amount of the colorant (colorant content in the colored layer) can be increased. As a result, particularly when the black colored layer is formed, a colored layer having an extremely low total light transmittance and having an excellent concealing property can be formed. In one embodiment, the binder resin is an acrylic resin, preferably an acrylic resin containing a polyfunctional monomer (e.g., pentaerythritol triacrylate) as a copolymerization component. When the acrylic resin containing a polyfunctional monomer as a copolymerization component is used, a colored layer having an appropriate modulus of elasticity can be formed, and hence blocking can be satisfactorily prevented in the case where the retardation film is rolled into a roll shape. Besides, a step resulting from the thickness of the printed layer is formed, and the step can effectively function in preventing the blocking.

Any appropriate colorant may be used as the colorant depending on purposes. Specific examples of the colorant include: inorganic pigments, such as titanium white, zinc white, carbon black, iron black, iron oxide red, chrome vermilion, ultramarine, cobalt blue, chrome yellow, and titanium yellow; organic pigments or dyes, such as phthalocyanine blue, indanthrene blue, isoindolinone yellow, benzidine yellow, quinacridone red, polyazo red, perylene red, and aniline black; metal pigments formed of scale-like foil pieces of aluminum, brass, and the like; and pearlescent pigments (pearl pigments) formed of scale-like foil pieces of titanium dioxide-coated mica, basic lead carbonate, and the like. When the black colored layer is formed, carbon black, iron black, or aniline black is suitably used. In this case, the colorants are preferably used in combination thereof. This is because a colored layer having no hue (that is, being jet black) by absorbing visible light in a wide range and uniformly can be formed. For example, in addition to the above-mentioned colorant, an azo compound and/or a quinone compound may be used. In one embodiment, the colorant contains the carbon black as a main component and another colorant (e.g., an azo compound and/or a quinone compound). According to such configuration, a colored layer having no hue and being excellent in temporal stability can be formed. When the black colored layer is formed, the colorant may be used at a ratio of preferably from 50 parts by weight to 200 parts by weight with respect to 100 parts by weight of the binder resin. In this case, the content of the carbon black in the colorant is preferably from 80% to 100%. When the colorant (in particular, the carbon black) is used at such ratio, a colored layer having an extremely low total light transmittance and being excellent in temporal stability can be formed.

The thickness of the printed layer is preferably from 3 μm to 5 μm. Further, the printed layer has a total light transmittance at a thickness of from 3 μm to 5 μm of preferably 0.01% or less, more preferably 0.008% or less. When the total light transmittance falls within such range, a non-display region of an organic EL display apparatus can be satisfactorily concealed without using a bezel.

C. Second Optical Laminate

The thickness of the second optical laminate is 300 μm or less, preferably 280 μm or less, more preferably 260 μm or less, still more preferably 250 μm or less, particularly preferably 200 μm or less. When the thickness falls within such range, an organic EL display apparatus that is thin and excellent in bendability, and that is hardly broken even when repeatedly bent can be obtained. In addition, an organic EL display apparatus in which warping is reduced can be obtained. The lower limit of the thickness of the second optical laminate, which depends on its configuration, is, for example, 20 μm.

The equilibrium moisture content of the second optical laminate is 2.5% or less. When the equilibrium moisture content falls within such range, an organic EL display apparatus in which the occurrence of warping due to a change in its temperature and humidity environment is suppressed can be obtained. The equilibrium moisture content of the second optical laminate is preferably 2% or less, more preferably 1.5% or less. When the equilibrium moisture content falls within such range, the above-mentioned effect of the present invention becomes more remarkable. The equilibrium moisture content of the second optical laminate is preferably as small as possible, but its lower limit is, for example, 0.1%.

When heated (80° C.×24 h), the second optical laminate has a shrinkage ratio of preferably 1.0% or less, more preferably 0.8% or less, still more preferably 0.5% or less with respect to its area before the heating. When the shrinkage ratio falls within such range, the occurrence of warping due to a change in the environment can be suppressed.

The tensile modulus of elasticity of the second optical laminate is preferably from 1.5 GPa to 10 GPa, more preferably from 2 GPa to 8 GPa at 25° C. When the tensile modulus of elasticity falls within such range, the optical laminate can be made excellent in bendability and less liable to be broken.

In one embodiment, the second optical laminate has an elongate shape.

As described above, in one embodiment, the second optical laminate includes the substrate and the pressure-sensitive adhesive layer arranged on the substrate. As the substrate, the substrate described in the section B-1 may be used. As the pressure-sensitive adhesive layer, the pressure-sensitive adhesive layer described in the section B-4 may be used.

D. Organic EL Panel

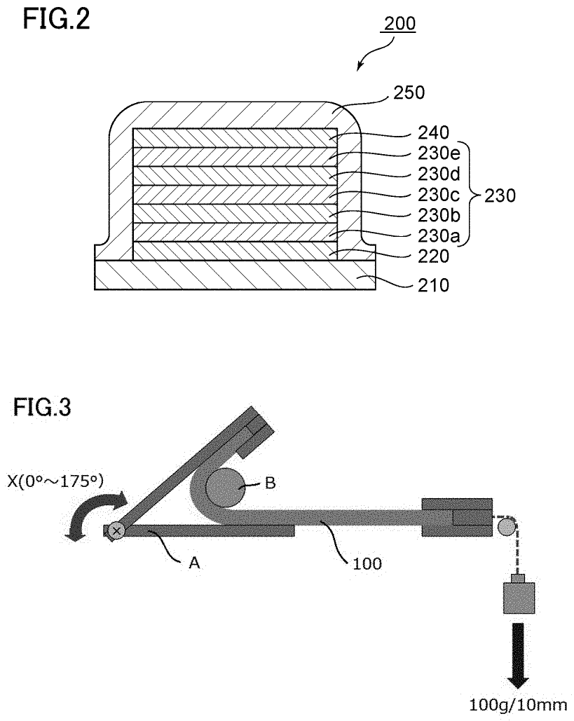

Any appropriate organic EL panel may be adopted as the organic EL panel as long as the effects of the present invention are obtained. FIG. 2 is a schematic sectional view for illustrating one mode of the organic EL panel to be used in the present invention. The organic EL panel 200 typically includes a substrate 210, a first electrode 220, an organic EL layer 230, a second electrode 240, and a sealing layer 250 for covering these components. The organic EL panel 200 may further include any appropriate layer as required. For example, a planarizing layer (not shown) may be arranged on the substrate, or an insulating layer (not shown) for preventing a short circuit may be arranged between the first electrode and the second electrode.

The substrate 210 may be formed of any appropriate material as long as the substrate 210 is bendable with the above-mentioned predetermined radius of curvature. The substrate 210 is typically formed of a material having flexibility. The use of the substrate having flexibility enables the following in addition to the above-mentioned effect of the present invention: when a circularly polarizing plate having an elongate shape is used, the organic EL display apparatus can be manufactured by a so-called roll-to-roll process, and hence can be mass-produced at low cost. Further, the substrate 210 is preferably formed of a material having a barrier property. Such substrate can protect the organic EL layer 230 from oxygen or moisture. Specific examples of the material having a barrier property and flexibility include thin glass provided with flexibility, a film of a thermoplastic resin or thermosetting resin provided with a barrier property, an alloy, and a metal. Examples of the thermoplastic resin or the thermosetting resin include a polyester-based resin, a polyimide-based resin, an epoxy-based resin, a polyurethane-based resin, a polystyrene-based resin, a polyolefin-based resin, a polyamide-based resin, a polycarbonate-based resin, a silicone-based resin, a fluorine-based resin, and an acrylonitrile-butadiene-styrene copolymer resin. Examples of the alloy include stainless steel, alloy 36, and alloy 42. Examples of the metal include copper, nickel, iron, aluminum, and titanium. The thickness of the substrate is preferably from 5 μm to 500 μm, more preferably from 5 μm to 300 μm, still more preferably from 10 μm to 200 μm. With such thickness, the organic EL display apparatus can be made bendable with the above-mentioned predetermined radius of curvature, and an excellent balance among flexibility, handleability, and mechanical strength is achieved. In addition, the organic EL panel can be suitably used in the roll-to-roll process.

The first electrode 220 can typically function as an anode. In this case, a material for forming the first electrode is preferably a material having a large work function from the viewpoint of facilitating the injection of a hole. Specific examples of such material include: transparent conductive materials, such as indium tin oxide (ITO), indium zinc oxide (IZO), indium tin oxide doped with silicon oxide (ITSO), indium oxide containing tungsten oxide (IWO), indium zinc oxide containing tungsten oxide (IWZO), indium oxide containing titanium oxide (ITiO), indium tin oxide containing titanium oxide (ITTiO), and indium tin oxide containing molybdenum (ITMO); and metals, such as gold, silver, and platinum, and alloys thereof.

The organic EL layer 230 is a laminate including various organic thin films. In the illustrated example, the organic EL layer 230 includes: a hole-injecting layer 230a formed of a hole injectable organic material (e.g., a triphenylamine derivative), and formed so as to improve the hole injection efficiency from an anode; a hole-transporting layer 230b formed of, for example, copper phthalocyanine; a light-emitting layer 230c formed of a luminous organic substance (e.g., anthracene, bis[N-(1-naphthyl)-N-phenyl]benzidine, or N,N′-diphenyl-N-N-bis (1-naphthyl) -1,1 ‘- (biphenyl) -4,4 ’-diamine (NPB)); an electron-transporting layer 230d formed of, for example, an 8-quinolinol aluminum complex; and an electron-injecting layer 230e formed of an electron injectable material (e.g., a perylene derivative or lithium fluoride), and formed so as to improve the electron injection efficiency from a cathode. The organic EL layer 230 is not limited to the illustrated example, and any appropriate combination that can cause light emission through the recombination of an electron and a hole in the light-emitting layer 230c may be adopted. The thickness of the organic EL layer 230 is preferably as small as possible. This is because the layer preferably transmits the emitted light to the extent possible. The organic EL layer 230 may be formed of an extremely thin laminate having a thickness of, for example, from 5 nm to 200 nm, preferably about 10 nm.

The second electrode 240 can typically function as a cathode. In this case, a material for forming the second electrode is preferably a material having a small work function from the viewpoint of facilitating the injection of an electron to improve luminous efficiency. Specific examples of such material include aluminum, magnesium, and alloys thereof.

The sealing layer 250 is formed of any appropriate material. The sealing layer 250 is preferably formed of a material excellent in barrier property and transparency. Typical examples of the material for forming the sealing layer include an epoxy resin and polyurea. In one embodiment, the sealing layer 250 maybe formed by applying the epoxy resin (typically an epoxy resin adhesive) and bonding a barrier sheet onto the resin.

It is preferred that the organic EL panel 200 may be continuously manufactured by the roll-to-roll process. The organic EL panel 200 maybe manufactured by, for example, a procedure in accordance with the procedure described in JP 2012-169236 A, the description of which is incorporated herein by reference. Further, the organic EL panel 200 may be continuously laminated with the optical laminate 100 that has an elongate shape by the roll-to-roll process, to thereby continuously manufacture the organic EL display apparatus 300.

Details of the bendable organic EL display apparatus are described in, for example, JP 4601463 B2 and JP 4707996 B2, the descriptions of which are incorporated herein by reference.

### EXAMPLES

Now, the present invention is specifically described by way of Examples. However, the present invention is by no means limited to these Examples. Evaluation methods in Examples are as described below. In addition, in Examples, the terms apart(s)” and “%” are by weight unless otherwise stated.

(1) Equilibrium Moisture Contents of First Optical Laminate and Second Optical Laminate

A first optical laminate and a second optical laminate were each cut to a size of 100 mm×150 mm to serve as a measurement sample. The sample was left to stand at a humidity of 55% and a temperature of 23° C. for 24 hours, and then the weight (a) of the sample was measured. The sample was put at 120° C. for 5 hours, and its weight (b) immediately after removal therefrom was measured. An equilibrium moisture content was calculated by the following expression.

Equilibrium moisture content (%): (a−b)/a×100

(2) Folding Endurance Test

A folding endurance tester manufactured by Imoto Machinery Co., Ltd. illustrated in FIG. 3 was used.

One end of the organic EL display apparatus 100 was fixed to a bendable jig A, and a predetermined load (100 g/10 mm) was applied to the other end. The jig A was bent with the substrate side being inside to hold a 10 mmφ mandrel B (i.e., the bent portion had a radius of curvature of 5 mm). In this manner, the organic EL display apparatus 100 was bent from a flat state until a bending angle X reached 175°. The mandrel used had a surface subjected to fluorine-containing alumite treatment (TUFRAM (trademark)).

The bending was performed 100,000 times (the jig was moved back and forth 100,000 times), and then visual observation and microscopic observation were performed to confirm the presence or absence of breakage, cracking, and delamination in the display apparatus.

A case in which the breakage, cracking, and delamination in the display apparatus were not confirmed is marked with Symbol “o”, and a case in which the breakage, cracking, and delamination in the display apparatus were confirmed is marked with Symbol “x”.

(3) Warping

An organic EL display apparatus (rectangular shape having a diagonal line of 5 inches) was placed on a horizontal surface, and the height of each of its four corners from the horizontal surface was measured. The average value of the four measured values was defined as a warping amount.
oo: No warping
o: The warping amount is 1 mm or less.
Δ: The warping amount is from 1 mm to 3 mm or less. There is no problem in actual use.
×: _{T}he warping amount is more than 3 mm. There is a problem in actual use.

(4) Modulus of Elasticity

The modulus of elasticity of a second optical laminate was measured in conformity to JIS K 7127 (test piece: dumbbell test piece).

### Example 1

### (Production of Polarizer A)

A polarizer (thickness: 5 μm) was obtained by the same method as that of Example 1 of JP 2016-126130 A.

### (Production of Retardation Film A)

A retardation film (thickness: 55 μm) was obtained by the same method as that of Example 1 of JP 2016-126130 A.

### (Production of Pressure-sensitive Adhesive Layer)

A four-necked flask with a stirring blade, a thermometer, a nitrogen gas inlet tube, and a condenser was loaded with 99 parts by weight of butyl acrylate, 1 part by weight of 4-hydroxybutyl acrylate, 0.2 part by weight of 2,2 ‘-azobisisobutyronitrile serving as a polymerization initiator, and 200 parts by weight of ethyl acetate serving as a polymerization solvent, and nitrogen purging was sufficiently performed. After that, under a stream of nitrogen, the stirred contents were subjected to a polymerization reaction for 10 hours with the liquid temperature in the flask being kept around 55° C. to prepare an acrylic polymer solution. The acrylic polymer had a weight-average molecular weight of 1,500,000.

100 Parts by weight of the solid content of the acrylic polymer solution was uniformly mixed under stirring with 0.2 part by weight of dibenzoyl peroxide (manufactured by Nippon Oil & Fats Co., Ltd., product name: “NYPERBMT”) serving as a peroxide, 0.2 part by weight of a trimethylolpropane/tolylene diisocyanate adduct (manufactured by Nippon Polyurethane Industry Co., Ltd., product name: “CORONATE L”) serving as an isocyanate-based cross-linking agent, and 0.1 part by weight of a silane coupling agent (manufactured by Shin-Etsu Chemical Co., Ltd., product name: “KBM403”) to prepare an acrylic pressure-sensitive adhesive solution A (solid content: 15 wt %).

The acrylic pressure-sensitive adhesive solution was applied onto a separator formed of a release-treated polyethylene terephthalate film (thickness: 38 μm), and heated at 155° C. for 1 minute to form a pressure-sensitive adhesive layer having a thickness after drying of 50 μm.

### (Production of First Optical Laminate A)

A polyarylate resin film (thickness: 40 μm) serving as a substrate, the polarizer A, and the retardation film A were bonded in the stated order via an adhesive (thickness: 1 μm). Further, the pressure-sensitive adhesive layer was transferred onto the surface of the retardation film A on the opposite side to the polarizer A to provide a first optical laminate A having a total thickness of 152 μm (substrate (40 μm)/adhesive (1 μm)/polarizer A (5 μm)/adhesive (1 μm)/retardation film A (55 μm)/pressure-sensitive adhesive layer (50 μm)). In this case, an angle formed between the absorption axis of the polarizer A and the slow axis of the retardation film A was set to 48°.

The resultant first optical laminate A was subjected to the above-mentioned evaluation (1). The result is shown in Table 2.

(Production of Second Optical Laminate A)

85 Parts by weight of a polyol having three OH groups (manufactured by Asahi Glass Co., Ltd., product name: “PREMINOL S3011”, Mn=10,000), 13 parts by weight of a polyol having three OH groups (manufactured by Sanyo Chemical Industries, Ltd., product name: “SANNIX GP-3000”, Mn=3,000), 2 parts by weight of a polyol having three OH groups (manufactured by Sanyo Chemical Industries, Ltd., product name: “SANNIX GP-1000”), 18 parts by weight of a polyfunctional alicyclic isocyanate compound (manufactured by Nippon Polyurethane Industry Co., Ltd., product name: “CORONATE HX”), 0.04 part by weight of a catalyst (manufactured by Nihon Kagaku Sangyo Co., Ltd., product name: “Nacem Ferric Iron”), 0.5 part by weight of an antidegradant (manufactured by BASF SE, product name: “Irganox 1010”), 30 parts by weight of a fatty acid ester (isopropyl myristate, manufactured by Kao Corporation, product name: “EXCEPARL IPM”, Mn=270), 1.5 parts by weight of 1-ethyl-3-methylimidazolium bis (fluoromethanesulfonyl) imide (manufactured by DKS Co. Ltd., product name: “AS110”), 0.01 part by weight of a both-end-type polyether-modified silicone oil (manufactured by Shin-Etsu Chemical Co., Ltd., product name: “KF-6004”), and 241 parts by weight of ethyl acetate serving as a diluting solvent were blended and stirred with a disper to provide a urethane-based pressure-sensitive adhesive composition B.

The urethane-based pressure-sensitive adhesive composition was applied to a polyester resin substrate (manufactured by Toray Industries, Inc., product name: “Lumirror S10”, thickness: 38 μm) with a fountain roll, and was cured and dried under the conditions of a drying temperature of 130° C. and a drying time of 3 minutes to provide a second optical laminate A having a total thickness of 63 μm (substrate (38 μm)/pressure-sensitive adhesive layer (25 μm)).

The resultant second optical laminate A was subjected to the above-mentioned evaluations (1) and (4). The results are shown in Table 2.

(Production of Organic EL Display Apparatus)

The first optical laminate A and the second optical laminate A were each cut into a size of 5 inches, and the pressure-sensitive adhesive layer side of the first optical laminate A was bonded to the viewer side of a 5-inch organic EL panel. Then, the pressure-sensitive adhesive layer side of the second optical laminate A was bonded to the back surface side of the organic EL panel. Thus, an organic EL display apparatus was obtained.

The resultant organic EL display apparatus was subjected to the above-mentioned evaluations (2) and (3). The results are shown in Table 2.

### Example 2

### (Production of First Optical Laminate B)

An optical compensation layer A (thickness: 3 μm) formed of a liquid crystal alignment fixed layer (first liquid crystal alignment fixed layer (λ/2 plate) and a second liquid crystal alignment fixed layer (λ/4 plate)) was formed by the same method as that of Example 2 of JP 2016-126130 A.

A first optical laminate B having a total thickness of 100 μm (substrate (40 μm)/adhesive (1 μm)/polarizer A (5 μm)/adhesive (1 μm) /optical compensation layer A (3 μm) formed of liquid crystal alignment fixed layers/pressure-sensitive adhesive layer (50 μm)) was obtained in the same manner as in Example 1 except that the optical compensation layer A was arranged in place of the retardation film A. The optical compensation layer A formed of liquid crystal alignment fixed layers was arranged so that the first liquid crystal alignment fixed layer was on the polarizer A side. In addition, an angle formed between the slow axis of the first liquid crystal alignment fixed layer and the absorption axis of the polarizer was set to 15°, and an angle formed between the slow axis of the second liquid crystal alignment fixed layer and the absorption axis of the polarizer was set to 75°.

The resultant first optical laminate B was subjected to the above-mentioned evaluation (1). The result is shown in Table 2.

(Production of Organic EL Display Apparatus)

An organic EL display apparatus was obtained in the same manner as in Example 1 except that the first optical laminate B was used in place of the first optical laminate A.

The resultant organic EL display apparatus was subjected to the above-mentioned evaluations (2) and (3). The results are shown in Table 2.

### Example 3

### (Production of ITO Film)

A thermosetting resin formed of a melamine resin, an alkyd resin, and an organic silane condensate (melamine resin:alkyd resin:organic silane condensate=2:2:1 in weight ratio) was applied to one surface of a substrate (refractive index: 1.65) formed of a polyethylene terephthalate film having a thickness of 50 μm, and the applied resin was cured to form a transparent dielectric (undercoat) layer having a thickness of 35 nm (refractive index: 1.54).

Then, on the transparent dielectric layer, an ITO film having a thickness of 22 nm (refractive index: 2.00) was formed as a transparent conductive layer under an atmosphere of a mixed gas (0.5 Pa) of 95% of argon gas and 5% of oxygen gas by a reactive sputtering method using a sintered material of 97 wt % of indium oxide and 3 wt % of tin oxide. The film was heated under the condition of 140° C. for 60 minutes to crystallize the ITO film. Thus, an ITO film having a thickness of 50 μm was produced.

### (Production of First Optical Laminate C)

Apolyarylate resin film (thickness: 40 μm) serving as a cover film, a pressure-sensitive adhesive layer (thickness: 50 μm) formed from the acrylic pressure-sensitive adhesive solution A, a polyimide resin film (thickness: 20 μm) serving as a substrate, an adhesive layer (thickness: 1 μm), the polarizer A (thickness: 5 μm), an adhesive layer (thickness: 1 μm), the optical compensation layer A (thickness: 3 μm) formed of liquid crystal alignment fixed layers, a pressure-sensitive adhesive layer (thickness: 20 μm) formed from the acrylic pressure-sensitive adhesive solution A, the ITO film (thickness: 50 μm), and a pressure-sensitive adhesive layer (thickness: 50 μm) formed from the acrylic pressure-sensitive adhesive solution A were laminated in the stated order to produce a first optical laminate C having a total thickness of 240 μm. The optical compensation layer A formed of liquid crystal alignment fixed layers was arranged so that the first liquid crystal alignment fixed layer was on the polarizer A side. In addition, an angle formed between the slow axis of the first liquid crystal alignment fixed layer and the absorption axis of the polarizer was set to 15°, and an angle formed between the slow axis of the second liquid crystal alignment fixed layer and the absorption axis of the polarizer was set to 75°.

The resultant first optical laminate C was subjected to the above-mentioned evaluation (1). The result is shown in Table 2.

(Production of Organic EL Display Apparatus)

An organic EL display apparatus was obtained in the same manner as in Example 1 except that the first optical laminate C was used in place of the first optical laminate A.

The resultant organic EL display apparatus was subjected to the above-mentioned evaluations (2) and (3). The results are shown in Table 2.

### Example 4

### (Production of Second Optical Laminate B)

A second optical laminate B having a total thickness of 125 μm was produced in the same manner as in Example 1 except that: the thickness of the polyester resin substrate was changed to 75 μm; and the thickness of the pressure-sensitive adhesive layer was changed to 50 μm.

The resultant second optical laminate B was subjected to the above-mentioned evaluations (1) and (4). The results are shown in Table 2.

(Production of Organic EL Display Apparatus)

An organic EL display apparatus was obtained in the same manner as in Example 3 except that the second optical laminate B was used in place of the second optical laminate A.

The resultant organic EL display apparatus was subjected to the above-mentioned evaluations (2) and (3). The results are shown in Table 2.

### Example 5

### (Production of Polarizer B)

A polarizer B (thickness: 22 μm) was obtained by the same method as that of Comparative Example 1 of JP 2016-126130 A.

### (Production of First Optical Laminate D)

A first optical laminate D having a total thickness of 257 μm (polyarylate resin film (40 μm)/pressure-sensitive adhesive layer (50 μm)/substrate (20 μm)/adhesive layer (1 μm)/polarizer B (22 μm)/adhesive layer (1 μm)/optical compensation layer A (3 μm) formed of liquid crystal alignment fixed layers/pressure-sensitive adhesive layer (20 μm)/ITO film (50 μm)/pressure-sensitive adhesive layer (50 μm)) was obtained in the same manner as in Example 3 except that the polarizer B was used in place of the polarizer A.

The resultant first optical laminate D was subjected to the above-mentioned evaluation (1). The result is shown in Table 2.

(Production of Organic EL Display Apparatus)

An organic EL display apparatus was obtained in the same manner as in Example 3 except that: the first optical laminate D was used in place of the first optical laminate C; and the second optical laminate B was used in place of the second optical laminate A.

The resultant organic EL display apparatus was subjected to the above-mentioned evaluations (2) and (3). The results are shown in Table 2.

### Comparative Example 1

### (Production of First Optical Laminate E)

A first optical laminate E having a total thickness of 312 μm was obtained in the same manner as in Example 3 except that: a triacetylcellulose film (thickness: 40 μm) was used in place of the polyimide resin film serving as a substrate; and the retardation film A (thickness: 55 μm) was used in place of the optical compensation layer A formed of liquid crystal alignment fixed layers.

The resultant first optical laminate E was subjected to the above-mentioned evaluation (1). The result is shown in Table 2.

(Production of Organic EL Display Apparatus)

An organic EL display apparatus was obtained in the same manner as in Example 3 except that the first optical laminate E was used in place of the first optical laminate C.

The resultant organic EL display apparatus was subjected to the above-mentioned evaluations (2) and (3). The results are shown in Table 2.

### Comparative Example 2

### (Production of First Optical Laminate F)

A first optical laminate F was obtained in the same manner as in Example 1 except that the polarizer B (thickness: 22 μm) was used in place of the polarizer A.

The resultant first optical laminate F was subjected to the above-mentioned evaluation (1). The result is shown in Table 2.

(Production of Organic EL Display Apparatus)

An organic EL display apparatus was obtained in the same manner as in Example 1 except that the first optical laminate F was used in place of the first optical laminate A.

The resultant organic EL display apparatus was subjected to the above-mentioned evaluations (2) and (3). The results are shown in Table 2.

### Comparative Example 3

### (Production of First Optical Laminate G)

A first optical laminate G having a total thickness of 400 μm (polyarylate resin film (200 μm)/pressure-sensitive adhesive layer (50 μm)/substrate (20 μm)/adhesive layer (1 μm)/polarizer A (5 μm)/adhesive layer (1 μm) /optical compensation layer A (3 μm) formed of liquid crystal alignment fixed layers/pressure-sensitive adhesive layer (20 μm)/ITO film (50 μm) /pressure-sensitive adhesive layer (50 μm)) was obtained in the same manner as in Example 3 except that a polyarylate resin film (thickness: 100 μm) was used in place of the polyarylate resin film (thickness: 40 μm) serving as a cover film.

The resultant first optical laminate G was subjected to the above-mentioned evaluation (1). The result is shown in Table 2.

(Production of Second Optical Laminate C)

A second optical laminate C having a total thickness of 250 μm was produced in the same manner as in Example 1 except that: the thickness of the polyester resin substrate was changed to 150 μm; and the thickness of the pressure-sensitive adhesive layer was changed to 100 μm.

The resultant second optical laminate C was subjected to the above-mentioned evaluations (1) and (4). The results are shown in Table 2.

(Production of Organic EL Display Apparatus)

An organic EL display apparatus was obtained in the same manner as in Example 3 except that: the first optical laminate G was used in place of the first optical laminate C; and the second optical laminate C was used in place of the second optical laminate A.

The resultant organic EL display apparatus was subjected to the above-mentioned evaluations (2) and (3). The results are shown in Table 2.

In Table 1, the configurations of the organic EL display apparatus produced in Examples and Comparative Examples are summarized. In Table 1, the description of the adhesive layers is omitted.

TABLE 1

| Example 1 | | | Example 2 | | | Example 3 | | | Example 4 | | |
|---|---|---|---|---|---|---|---|---|---|---|---|
| First | Substrate | 40 μm | First | Substrate | 40 μm | First | Cover film | 40 μm | First | Cover film | 40 μm |
| optical | Polarizer A | 5 μm | optical | Polarizer A | 5 μm | optical | Pressure-sensitive | 50 μm | optical | Pressure- | 50 μm |
| laminate | Retardation | 55 μm | laminate | Alignment fixed | 3 μm | laminate | adhesive | | laminate | sensitive | |
| A | film A | | B | layer A | | C | layer | | C | adhesive | |
| | Pressure-sensitive | 50 μm | | Pressure-sensitive | 50 μm | | Substrate | 20 μm | | layer | |
| | adhesive | | | adhesive | | | Polarizer A | 5 μm | | Substrate | 20 μm |
| | layer | | | layer | | | Alignment fixed | 3 μm | | Polarizer A | 5 μm |
| | | | | Pressure-sensitive | 25 μm | | layer A | | | Alignment | 3 μm |
| | | | | adhesive | | | Pressure-sensitive | 20 μm | | fixed | |
| | | | | layer | | | adhesive | | | layer A | |
| | | | | | | | layer | | | Pressure- | 20 μm |
| Organic EL panel | | | Organic EL panel | | | | | | | sensitive | |
| Second | Pressure-sensitive | 25 μm | Second | Pressure-sensitive | 25 μm | | | | | adhesive | |
| optical | adhesive | | optical | adhesive | | | | | | layer | |
| laminate | layer | | laminate | layer | | | ITO film | 50 μm | | ITO film | 50 μm |
| A | Substrate | 38 μm | A | Substrate | 38 μm | | Pressure-sensitive | 50 μm | | Pressure- | 50 μm |
| | | | | | | | adhesive | | | sensitive | |
| | | | | | | | layer | | | adhesive | |
| | | | | | | | | | | layer | |
| | | | | | | Organic EL panel | | | Organic EL panel | | |
| | | | | | | Second | Pressure-sensitive | 25 μm | Second | Pressure- | 50 μm |
| | | | | | | optical | adhesive | | optical | sensitive | |
| | | | | | | laminate | layer | | laminate | adhesive | |
| | | | | | | A | Substrate | 38 μm | B | layer | |
| | | | | | | | | | | Substrate | 75 μm |
| Example 5 | | | Comparative Example 1 | | | Comparative Example 2 | | | Comparative Example 3 | | |
| First | Cover film | 40 um | First | Cover film | 40 μm | First | Substrate | 40 μm | First | Cover film | 200 μm |
| optical | Pressure-sensitive | 50 μm | optical | Pressure-sensitive | 50 μm | optical | Polarizer B | 22 μm | optical | Pressure- | 50 μm |
| laminate | adhesive | | laminate | adhesive | | laminate | Retardation | 55 μm | laminate | sensitive | |
| D | layer | | E | layer | | F | film A | | G | adhesive | |
| | Substrate | 20 μm | | Substrate | 40 μm | | Pressure-sensitive | 50 μm | | layer | |
| | Polarizer B | 22 μm | | Polarizer A | 5 μm | | adhesive | | | Substrate | 20 μm |
| | Alignment fixed | 3 μm | | Retardation | 55 μm | | layer | | | Polarizer A | 5 μm |
| | layer A | | | film A | | Organic EL panel | | | | Alignment | 3 μm |
| | Pressure-sensitive | 20 μm | | Pressure-sensitive | 20 μm | Second | Pressure-sensitive | 25 μm | | fixed | |
| | adhesive | | | adhesive | | optical | adhesive | | | layer A | |
| | layer | | | layer | | laminate | layer | | | Pressure- | 20 μm |
| | ITO film | 50 μm | | ITO film | 50 μm | A | substrate | 38 μm | | sensitive | |
| | Pressure-sensitive | 50 μm | | Pressure-sensitive | 50 μm | | | | | adhesive | |
| | adhesive | | | adhesive | | | | | | layer | |
| | layer | | | layer | | | | | | ITO film | 50 μm |
| Organic EL panel | | | Organic EL panel | | | | | | | Pressure- | 50 μm |
| Second | Pressure-sensitive | 50 μm | Second | Pressure-sensitive | 25 μm | | | | | sensitive | |
| optical | adhesive | | optical | adhesive | | | | | | adhesive | |
| laminate | layer | | laminate | layer | | | | | | layer | |
| B | Substrate | 75 μm | A | Substrate | 38 μm | | | | Organic EL panel | | |
| | | | | | | | | | Second | Pressure- | 100 μm |
| | | | | | | | | | optical | sensitive | |
| | | | | | | | | | laminate | adhesive | |
| | | | | | | | | | C | layer | |
| | | | | | | | | | | Substrate | 150 μm |

TABLE 2

| | | | | | | Difference | | | |
|---|---|---|---|---|---|---|---|---|---|
| | | | | | | between | | | |
| | | | Difference | | | equilibrium | | | |
| | | | between | | | moisture of | | | |
| | | | thicknesses | | | contents | | | |
| | | | of first | Equilibrium | Equilibrium | of first | Modulus | | |
| | Thickness | Thickness | optical | moisture | moisture | optical | elasticity | | |
| | of | of | laminate | content of | content of | laminate | of | | |
| | first | second | and second | first | second | and second | second | | |
| | optical | optical | optical | optical | optical | optical | optical | | |
| | laminate | laminate | laminate | laminate | laminate | laminate | laminate | Bending | |
| | (μm) | (μm) | (μm) | (%) | (%) | (%) | (GPa) | test | Warping |
| Example 1 | 152 | 63 | 89 | 1.0 | 0.3 | 0.7 | 3.5 | ∘ | ∘ |
| Example 2 | 100 | 63 | 37 | 0.9 | 0.3 | 0.6 | 3.2 | ∘ | ∘∘ |
| Example 3 | 240 | 63 | 177 | 0.7 | 0.3 | 0.4 | 4.1 | ∘ | Δ |
| Example 4 | 240 | 125 | 115 | 0.7 | 0.4 | 0.3 | 4.1 | ∘ | ∘ |
| Example 5 | 257 | 125 | 132 | 1.5 | 0.4 | 1.1 | 4.1 | ∘ | Δ |
| Comparative | 312 | 63 | 249 | 0.7 | 0.3 | 0.4 | 4.1 | x | x |
| Example 1 | | | | | | | | | |
| Comparative | 169 | 63 | 106 | 2.2 | 0.3 | 1.9 | 3.5 | ∘ | x |
| Example 2 | | | | | | | | | |
| Comparative | 400 | 250 | 150 | 0.2 | 0.4 | 0.2 | 70 | x | x |
| Example 3 | | | | | | | | | |

As apparent from Table 1, according to the present invention, the organic EL display apparatus which is excellent in bending resistance, and in which the occurrence of warping due to a change in its environment is suppressed can be provided by appropriately adjusting the thicknesses and equilibrium moisture contents of the first optical laminate and the second optical laminate.

### REFERENCE SIGNS LIST

100 organic EL display apparatus
200 organic EL panel
300 first optical laminate
400 second optical laminate

1. An organic EL display apparatus, comprising:
an organic EL panel;
a first optical laminate arranged on one side of the organic EL panel; and
a second optical laminate arranged on another side of the organic EL panel,
wherein the first optical laminate has a thickness of 300 μm or less,
wherein the second optical laminate has a thickness of 300 μm or less,
wherein the first optical laminate has an equilibrium moisture content of 2.5% or less, and
wherein the second optical laminate has an equilibrium moisture content of 2.5% or less.

2. The organic EL display apparatus according to claim 1, wherein an absolute value of a difference between the thickness of the first optical laminate and the thickness of the second optical laminate is 150 μm or less.

3. The organic EL display apparatus according to claim 1, wherein an absolute value of a difference between the equilibrium moisture content of the first optical laminate and the equilibrium moisture content of the second optical laminate is 1% or less.

4. The organic EL display apparatus according to claim 1, wherein the first optical laminate has a tensile modulus of elasticity of from 1.5 GPa to 10 GPa at 25° C.

5. The organic EL display apparatus according to claim 1, wherein the second optical laminate has a tensile modulus of elasticity of from 1.5 GPa to 10 GPa at 25° C.

6. The organic EL display apparatus according to claim 1, wherein the first optical laminate includes at least a substrate, a polarizer, an optical compensation layer, and a pressure-sensitive adhesive layer in the stated order.

7. The organic EL display apparatus according to claim 1, wherein the first optical laminate includes a conductive layer.

8. The organic EL display apparatus according to claim 1, wherein the organic EL display apparatus has a warping amount of 3 mm or less.

9. The organic EL display apparatus according to claim 1, wherein the organic EL display apparatus is bendable with a radius of curvature of 10 mm or less.
